(19) United States
(12) Patent Application Publication
(10) Pub. No.: US 2023/0395381 A1
(43) Pub. Date: Dec. 7, 2023

(54) ELECTRICAL DISCHARGE MACHINING OF SEMICONDUCTORS

(71) Applicant: Nielson Scientific, LLC, Lehi, UT (US)

(72) Inventor: Gregory NIELSON, Lehi, UT (US)

(21) Appl. No.: 18/250,203

(22) PCT Filed: Oct. 25, 2021
(86) PCT No.: PCT/US2021/056460

§ 371 Date: Apr. 21, 2023

Related U.S. Application Data
(60) Provisional application No. 63/104,951, filed on Oct. 23, 2020.

(51) Int. Cl. H01L 21/04; B23H 7/04; B23H 7/38; H01L 29/16

(52) U.S. Cl. CPC H01L 21/0475; B23H 7/04; B23H 7/38; H01L 29/1608

(57) ABSTRACT

An electrical discharge machining system includes a semiconductor workpiece, a voltage source, an EDM tool, and an illumination system. The illumination system is configured to illuminate the semiconductor workpiece in order to increase the conductivity of the semiconductor workpiece. The voltage source establishes an electric potential difference between the workpiece and the EDM tool while the illumination system illuminates the semiconductor workpiece. The electric potential difference is such that an electrical discharge occurs between the workpiece and the EDM tool, thereby removing material from the workpiece.

### RELATED APPLICATIONS

This application claims priority to U.S. Provisional Patent Application No. 63/104,951, filed on Oct. 23, 2020, and entitled “ENHANCED ELECTRICAL DISCHARGE MACHINING FOR SEMICONDUCTORS,” the entirety of which is incorporated herein by reference.

### STATEMENT OF GOVERNMENTAL INTEREST

This invention was made with Government support under Contract No. DE-SC0020854 awarded by the United States Department of Energy. The U.S. Government has certain rights in the invention.

### BACKGROUND

Electrical discharge machining (EDM) is a technique used to machine electrically conductive workpieces. In EDM, an electrical discharge between an EDM tool and a conductive workpiece is stimulated. The electrical discharge causes material to be selectively removed from the workpiece at a location depending upon positioning of the EDM tool. EDM relies in part on conductivity of the workpiece to form a complete circuit for return of electrical current during the electrical discharge. Conventionally, therefore, EDM has been unsuitable for use in machining semiconductors, which have substantially lower electrical conductivity than conducting metals like copper or aluminum.

EDM of a silicon carbide workpiece has been examined by Yamaguchi, Satarou, Toshiya Noro, Hideaki Takahashi, Hideyoshi Majima, Yoshihisa Nagao, Katsuhiko Ishikawa, You Zhou, and Tomohisa Kato. “Electric Discharge Machining for Silicon Carbide and Related Materials.” Materials Science Forum volumes 600-603, pages 851-854 (September 2008) (hereinafter “Yamaguchi, et al.”). Yamaguchi et al. considered the conductivity of a silicon carbide workpiece subject to three different types of effects: photoconduction, the avalanche effect, and thermal effects. Yamaguchi et al. tested a silicon carbide sample using voltages ranging from 100 V to 1.1 kV, and determined that the conductivity of the silicon carbide sample exhibited a non-linear increase at higher voltages due to the avalanche effect. Yamaguchi et al. also showed that irradiation of the sample by red and blue LEDs increased the current through the sample at a given voltage, with more current passing through the sample when the sample was subject to illumination by the blue LED than by the red LED.

Yamaguchi et al. state that the difference in sample current “depends on the energy of light and the band gap structure of the SiC.” Yamaguchi et al. further describe that at a peak voltage of 980 V and subject to direct illumination by “strong UV light,” EDM was possible with respect to a workpiece of silicon carbide. However, Yamaguchi et al. do not describe how the light energy is selected relative to the bandgap of silicon carbide or how illumination might be tailored for EDM of semiconductors other than silicon carbide. Yamaguchi et al. further do not indicate operability of EDM with respect to silicon carbide at lower voltages. Still further, Yamaguchi et al. appear only to depict that illumination occurs directly on a surface that is being machined by EDM.

### SUMMARY

The following is a brief summary of subject matter that is described in greater detail herein. This summary is not intended to be limiting as to the scope of the claims.

Technologies pertaining to EDM of semiconductors are described herein. In an exemplary embodiment of an EDM process, a workpiece is obtained, wherein the workpiece is formed from a semiconductor material. In a non-limiting example, the workpiece can be a silicon ingot that is to be cut into wafers. The workpiece can be connected to a first terminal of a voltage source that is used to drive the EDM process. An EDM tool can be connected to a second terminal of the voltage source. The EDM tool can be, for example, a wire or a block having a conductive face.

The workpiece is illuminated by an illumination system. The illumination system is configured to illuminate the workpiece with light that is near a bandgap energy of the semiconductor material of the workpiece. For example, a wavelength of the light can be selected such that photons incident on the semiconductor workpiece excite electrons from a first energy state in a valence band of the semiconductor to a second energy state in a conduction band of the semiconductor. With more particularity, in some exemplary embodiments the wavelength of the light can be selected such that photons incident on the semiconductor have an energy that is less than 110% of the bandgap energy of the semiconductor, less than 105% of the bandgap energy of the semiconductor, less than 102% of the bandgap energy of the semiconductor, or less than 100.5% of the bandgap energy of the semiconductor. Light that is below the bandgap energy of the semiconductor ordinarily does not have sufficient energy to stimulate generation of free charge carriers (i.e., by transitions of electrons from the valence band to the conduction band in the semiconductor). However, photons above but closer to the bandgap energy can generally penetrate farther into the semiconductor before being absorbed by the semiconductor and stimulating transition of an electron from the valence band to the conduction band than photons having energies farther from the bandgap energy. A photon energy of the light can be selected to be close to the bandgap energy of the semiconductor while still being above the bandgap energy to facilitate the light penetrating sufficiently far into the workpiece to reach a location that is desirably machined by EDM. Thus, in contrast with Yamaguchi et al., embodiments described herein are suited to providing indirect illumination of a machining location through a body of the workpiece.

While the workpiece is illuminated by the illumination system, the voltage source is controlled to establish a potential difference between the workpiece and the EDM tool. The potential difference established by the voltage source causes an electrical discharge between the EDM tool and the workpiece, thereby removing material from the workpiece. The increase in conductivity of the semiconductor workpiece resulting from illumination of the workpiece by the illumination system allows the electrical discharge to occur at voltages that are practical to generate with conventional voltage sources. Furthermore, the use of lower voltages than in conventional EDM systems allows for improved machining performance and lower surface roughness at an EDM location in a workpiece.

While light with sub-bandgap-energy photons is generally insufficient to stimulate free electrical carriers in a semiconductor workpiece, in some exemplary embodiments, the illumination system can be configured to illuminate the workpiece with light that has photon energy below the bandgap energy of the semiconductor. In such embodiments, the illumination system can be configured to stimulate multi-photon absorption (MPA) in the semiconductor. For example, the illumination system can be configured to direct emitted light to a focal spot that is on or within the semiconductor. Since the light has photon energy below the bandgap energy of the semiconductor, the light is able to pass through substantial portions of the semiconductor workpiece without being absorbed. The illumination system can be configured to emit the light with an intensity sufficient to cause MPA in the semiconductor given the size of the focal spot. Thus, at the focal spot the light can stimulate transitions of electrons from the valence band of the semiconductor to the conduction band. The illumination system can use the principle of MPA in order to illuminate specific locations within a semiconductor workpiece, increasing their local conductivity. In another embodiment, multiple beams of light can be directed into the workpiece from different directions to coincide at a location or multiple locations where EDM processing with higher material conductivity is desired.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1 is a diagram of an exemplary system for performing EDM with respect to a semiconductor workpiece.

FIG. 2 is a conceptual band structure diagram.

FIG. 3 is a partial cross-sectional view of an exemplary semiconductor workpiece.

FIG. 4 is a diagram of another exemplary system for performing EDM with respect to a semiconductor workpiece.

FIG. 5 is a diagram of yet another exemplary system for performing EDM with respect to a semiconductor workpiece.

FIG. 6 is a flow diagram that illustrates an exemplary methodology for performing EDM of a semiconductor workpiece.

FIG. 7 is an exemplary computing system.

### DETAILED DESCRIPTION

Various technologies pertaining to EDM of semiconductors are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Further, as used herein, the terms “component” and “system” are intended to encompass computer-readable data storage that is configured with computer-executable instructions that cause certain functionality to be performed when executed by a processor. The computer-executable instructions may include a routine, a function, or the like. It is also to be understood that a component or system may be localized on a single device or distributed across several devices. Additionally, as used herein, the term “exemplary” is intended to mean serving as an illustration or example of something, and is not intended to indicate a preference.

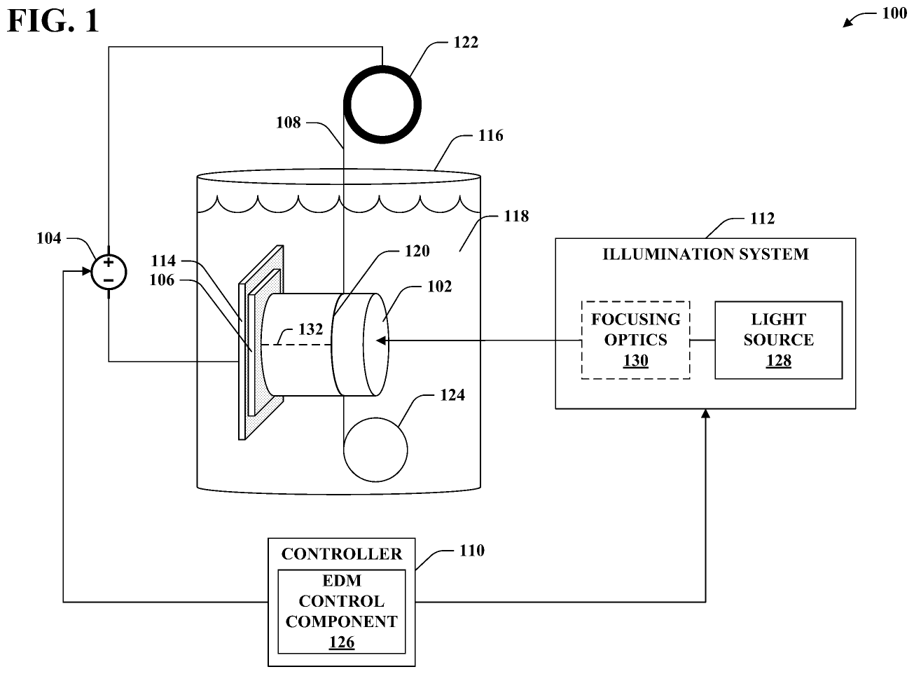

With reference to FIG. 1, an exemplary EDM system 100 that facilitates EDM of a semiconductor workpiece 102 is illustrated. The system 100 includes a voltage source 104, an electrode 106, an EDM tool 108, a controller 110, an illumination system 112, and a movable stage 114. The semiconductor workpiece 102 is positioned on the movable stage 114, such that a position of the semiconductor workpiece 102 relative to the EDM tool 108 can be changed to facilitate EDM of the workpiece 102 at a desired location in the workpiece 102. It is to be understood that in other embodiments, the semiconductor workpiece 102 can be positioned on a fixed stage, and a position of the EDM tool 108 can be changed to effectuate EDM of the workpiece 102 at a desired location in the workpiece 102.

The voltage source 104 is electrically connected to the electrode 106 and the wire EDM tool 108. The electrode 106 is electrically connected to the semiconductor work piece 102. In exemplary embodiments, the electrode 106 can be affixed to the semiconductor work piece 102 by way of a layer of electrically conductive adhesive. The voltage source 104 is therefore configured to establish an electric potential difference between the wire EDM tool 108 and the semiconductor workpiece 102. In some embodiments, the stage 114 can have a via formed therein to facilitate forming an electrical connection between the voltage source 104 and the electrode 106.

The controller 110 is configured to control operations of the voltage source 104 and the illumination system 112 to effectuate machining of the semiconductor workpiece 102 by way of the wire EDM tool 108 (e.g., by electrical discharge between the wire EDM tool 108 and the semiconductor workpiece 102). In exemplary embodiments, the controller 110 can be or include a computing device, a hardware logic component such as a field-programmable gate array (FPGA) or an application-specific integrated circuit (ASIC), a programmable logic controller (PLC), or the like. Briefly, the controller 110 is configured to control the illumination system 112 to illuminate the semiconductor workpiece 102, and further to control the voltage source 104 to establish an electric potential difference between the wire EDM tool 108 and the semiconductor workpiece 102. As will be described in greater detail below, the illumination of the semiconductor workpiece 102 by way of the illumination system 112 can increase a conductivity of the semiconductor workpiece 102 sufficiently to allow the electrical potential established by the voltage source 104 to cause an electrical discharge between the wire EDM tool 108 and the semiconductor workpiece 102, thereby removing material from the semiconductor work piece 102 at a cutting location.

The system 100 can further include a container 116 that has a dielectric fluid 118 disposed therein. The workpiece 102 can be disposed in the container 116 such that the workpiece 102 is submerged or immersed in the dielectric fluid 118. The dielectric fluid 118 can be any of various fluids that are disposed between the wire EDM tool 108 and the workpiece 102. In some embodiments, the dielectric fluid 118 can be a liquid such as de-ionized water, a dielectric oil, or other fluid (e.g., kerosene). In these embodiments, the dielectric fluid 118 can facilitate flushing of material from a cutting location, such as cutting location 120. Furthermore, in embodiments wherein the dielectric fluid 118 is a liquid, the dielectric fluid 118 may have an optical index that allows less light from the illumination system 112 to be reflected from the surface of the workpiece 102 than if the dielectric fluid 118 were air or some other gas. In other embodiments, however, the dielectric fluid 118 can be a gas, and the container 116 can be a sealed container that prevents leakage of the dielectric fluid 118 from the container 116.

The wire EDM tool 108 can be included on a spooling system. For example, the system 100 can include a first spool 122 and a second spool 124. A conductive wire is wrapped around the spools 122, 124, and a portion of the wire that extends between the spools 122, 124 functions as the wire EDM tool 108. As material is removed from the semiconductor workpiece 102 by electrical discharge between the workpiece 102 and the wire EDM tool 108, material is also removed from the wire EDM tool 108, causing degradation of the wire EDM tool 108. The spools 122, 124 can be affixed to motors (not shown) that are configured to turn the spools 122, 124, thereby causing a different portion of the wire wound around the spools 122, 124 to be exposed as the wire EDM tool 108. The controller 110 can control the motors to turn the spools 122, 124 during machining of the workpiece 102 by the wire EDM tool 108 so that the wire EDM tool 108 is continually refreshed with new wire.

The controller 110 includes an EDM control component 126. The EDM control component 126 is configured to control operations of each of the voltage source 104, the wire EDM tool 108 (e.g., by controlling operation of the spools 122, 124), the illumination system 112, and/or the movable stage 114 in order to effectuate machining of the workpiece 102. By way of example, the EDM control component 126 can control the stage 114 such that the wire EDM tool 108 moves through the cutting location 120 where a cut through the workpiece 102 is desirably made. In another example, the EDM control component 126 can control the voltage source 104 such that the voltage source 104 establishes a potential difference between the workpiece 102 and the wire EDM tool 108 when the tool 108 is positioned at locations where EDM is desirably performed on the workpiece 102. Continuing the example, the EDM control component 126 can control the voltage source 104 such that the voltage source 104 does not establish a potential difference between the workpiece 102 and the wire EDM tool 108 when the tool 108 is positioned at locations where EDM is not desirably performed on the workpiece 102. The EDM control component 126 can control the voltage source 104 such that the voltage source 104 operates in a pulsed mode or a continuous mode. In further embodiments, the EDM control component 126 can control the voltage source 104 to establish the potential difference with either of two polarities. The voltage source 104 can be configured to establish an electric potential difference between the electrode 106 and the EDM tool 1008 of less than or equal to 400V, less than or equal to 300V, or less than or equal to 200V.

Whereas EDM has been performed with conductive workpieces, such as metals, EDM has conventionally been difficult or impossible to perform with various semiconductor workpieces due to the substantially lower conductivity of semiconductors relative to conductive metals. The system 100 is configured to facilitate EDM of the semiconductor workpiece 102 by enhancing conductivity the semiconductor workpiece 102. With greater specificity, the illumination system 112 is configured to illuminate the workpiece 102 to generate free charge carriers in the workpiece 102, thereby increasing the electrical conductivity of the workpiece 102.

The illumination system 112 includes a light source 128. The light source 128 can be or include any of various types of light-emitting devices such as but not limited to a light-emitting diode (LED), a laser, a gas-discharge lamp, or substantially any other device that emits light. The light source 128 emits light that illuminates the semiconductor workpiece 102. In some embodiments, the container 116 can be substantially transparent such that light emitted by the light source 128 passes through a sidewall of the container 116 in order to illuminate the workpiece 102. In other embodiments, the container 116 can be formed of an opaque material and can include a transparent window through which light emitted by the light source 128 can pass in order to illuminate the workpiece 102. In still other embodiments, the illumination system 112 can be positioned inside the container 116 such that light emitted by the light source 128 can directly illuminate the workpiece 102 (e.g., after passing through the dielectric fluid 118). It is to be understood that the illumination system 112 can include substantially any number of light sources, and that functionality of the light source 128 described herein can be performed collectively by a plurality of light sources. The illumination system 112 can optionally include focusing optics 130 that are configured to focus light emitted by the light source 128, as will be described in greater detail below.

The light source 128 can be configured such that a photon energy of the light emitted by the light source 128 is close to the bandgap energy of a material of the semiconductor workpiece 102. By way of example, and not limitation, the photon energy of the light emitted by the light source 128 can be less than 110% of the bandgap energy of the workpiece, less than 105% of the bandgap energy of the workpiece 102, less than 102% of the bandgap energy of the workpiece 102, or less than 100.5% of the bandgap energy of the workpiece 102. For example, in embodiments wherein the semiconductor workpiece 102 comprises silicon carbide, the light emitted by the light source 128 can have a photon energy between 3.26 electron volts and 3.423 electron volts. In embodiments wherein the workpiece 102 is composed of silicon, the photon energy can be between 1.12 electron volts and 1.176 electron volts. In embodiments wherein the workpiece 102 is composed of germanium, the photon energy can be between 0.67 electron volts and 0.70 electron volts. In embodiments wherein the workpiece 102 is composed of gallium arsenide, the photon energy can be between 1.43 electron volts and 1.50 electron volts. In embodiments wherein the workpiece 102 is composed of gallium nitride, the photon energy can be between 3.4 electron volts and 3.57 electron volts.

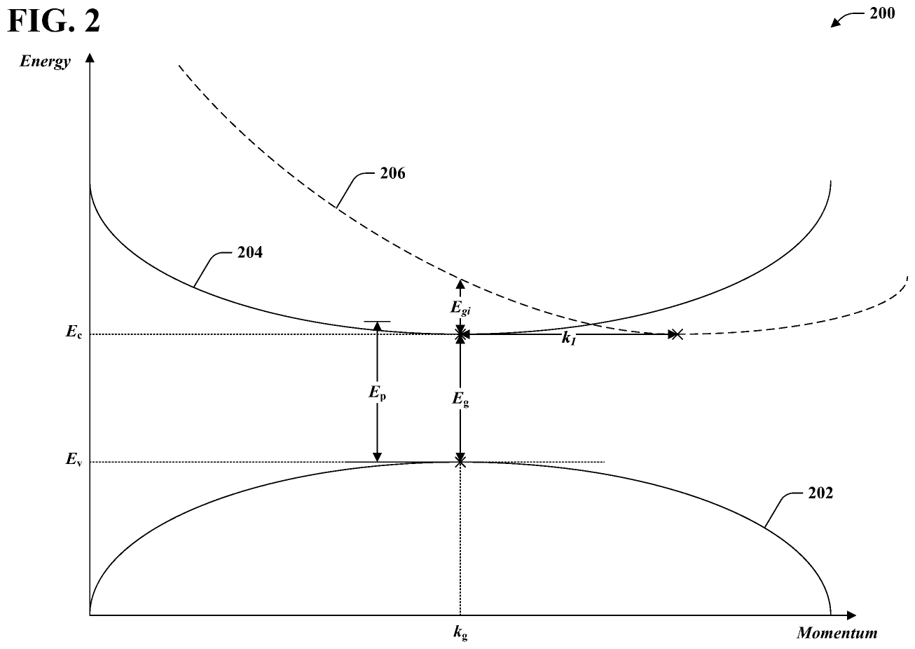

Referring now to FIG. 2, an exemplary band structure diagram 200 is shown. The band structure diagram depicts a valence band 202 and a conduction band 204 for a direct bandgap semiconductor. A maximal energy of the valence band 202, Eᵥ, is separated by a minimal energy of the conduction band 204, E_{c}, by a bandgap energy E_{g}. The energy of a photon of the light emitted by the light source 128, Eₚ, can be above but close to the bandgap energy E_{g}. Thus, photons emitted by the light source 128 have sufficient energy to stimulate migration of electrons from the valence band 202 to the conduction band 204. However, since the photon energy Eₚ is close to the bandgap energy E_{g} (e.g., less than 110% of the bandgap energy of the semiconductor 102, less than 105% of the bandgap energy of the semiconductor 102, less than 102% of the bandgap energy of the semiconductor 102, or less than 100.5% of the bandgap energy of the semiconductor 102), the light emitted by the light source 128 can penetrate further into the bulk of the semiconductor workpiece 102 than light having a greater energy.

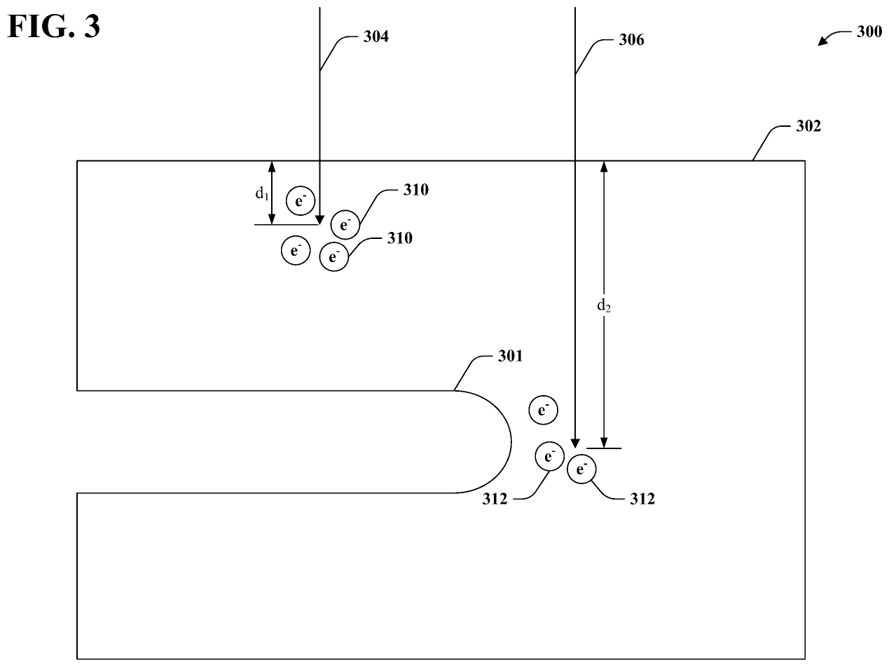

By way of example, and referring now to FIG. 3, a partial view 300 of an exemplary cut location 301 in a semiconductor workpiece 302 is illustrated, illustrating the effects of first light 304 and second light 306 within the semiconductor. The first light 304 is light that has a photon energy well above the bandgap energy of the semiconductor 302 (e.g., greater than 125% of the bandgap energy of the semiconductor 302). The first light 304 can be characterized by an average absorption depth of d₁, which is the average depth that a photon of the first light 304 penetrates into the semiconductor 302 before being absorbed by an electron, and thereby stimulating the electron from the valence band to the conduction band of the semiconductor 302. The first light 304 therefore tends to create free charge carriers (e.g., electrons 310) at the depth d₁. By contrast, the second light 306 is light that has a photon energy that is close to the bandgap energy of the semiconductor 302. Accordingly, the second light 306 is characterized by an average absorption depth of d₂ that is greater than the absorption depth d₁ of the first light 304. The second light 306 therefore tends to create free charge carriers (e.g., electrons 312) proximal to the depth d₂. The free charge carriers 312 created by the second light 306 increase the local conductivity of the semiconductor 302 proximal to the cut location 301, thereby facilitating EDM at the cut location 301.

Indirect bandgap semiconductors are characterized by the fact that a maximal energy of the valence band and the minimal energy of the conduction band do not occur at a same crystal momentum. For example, and referring once again to FIG. 2, the band structure diagram 200 depicts a conduction band 206 for an indirect bandgap semiconductor having the valence band 202 depicted in the diagram 200. The exemplary indirect bandgap conduction band 206 is shown as having the same minimal energy E_{c} as the direct bandgap conduction band 204, but is offset from the maximal energy Eᵥ of the valence band 202 by crystal momentum kᵢ. Accordingly, the likelihood of a photon being absorbed by a valence band electron in an indirect bandgap semiconductor (thereby stimulating that electron into the conduction band as a free charge carrier) depends in part upon the likelihood of incidence of a phonon resulting from vibration of the crystal structure of the semiconductor 102. For instance, in order for an electron of the indirect bandgap semiconductor at the crystal momentum k_{g} at which the direct bandgap semiconductor has its minimal bandgap energy E_{g} to absorb a photon, the photon would need energy Eᵢ=E_{g}+E_{gi}. Alternatively, the electron could simultaneously absorb a photon of energy E_{g} and a phonon of momentum k₁. Therefore, as a general matter, when the workpiece 102 is an indirect bandgap semiconductor, the light emitted by the light source 128 can have a greater energy relative to the bandgap energy of the semiconductor workpiece 102 than for a direct bandgap semiconductor in order to penetrate a same average distance. By way of example, for an indirect bandgap semiconductor the photon energy of the light emitted by the light source 128 can be less than 120% of the bandgap energy of the semiconductor 102, less than 115% of the bandgap energy of the semiconductor 102, less than 110% of the bandgap energy of the semiconductor 102, or less than 105% of the bandgap energy of the semiconductor 102.

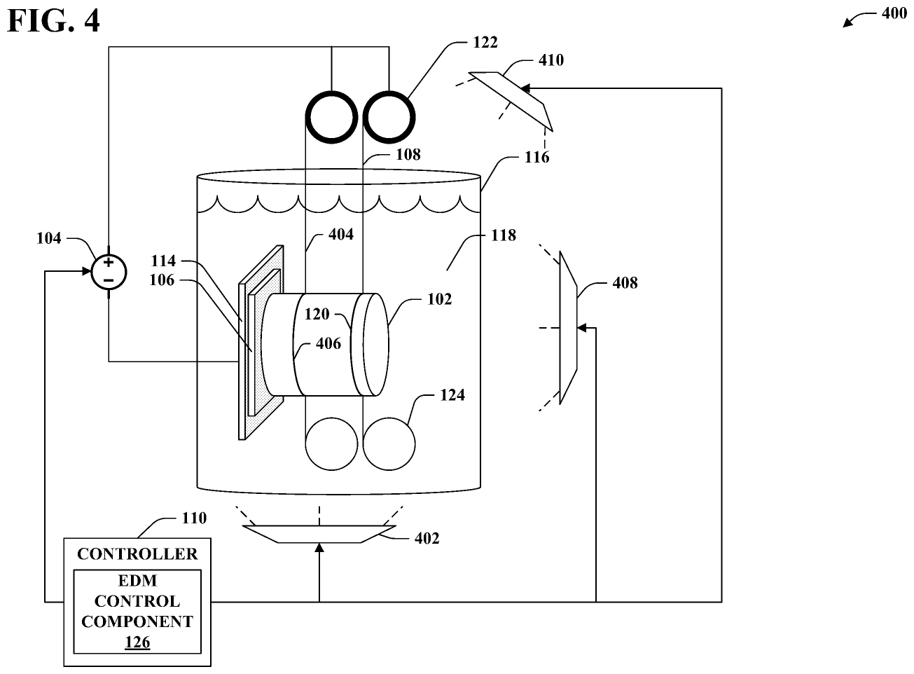

Referring once again to FIG. 1, in some embodiments the illumination system 112 can be configured for flood illumination of the semiconductor workpiece 102. In these embodiments, the illumination system 112 is configured to increase conductivity of the semiconductor workpiece 102 in a wide area. Enhancing conductivity of the semiconductor workpiece 102 in a wide area can also facilitate performing EDM by way of multiple EDM tools simultaneously. For example, and referring now to FIG. 4, another exemplary EDM system 400 is illustrated. The system 400 includes the workpiece 102, the voltage source 104, the electrode 106, the wire EDM tool 108, the controller 110, the stage 114, and the container 116 with the dielectric fluid 118, all configured in substantially similar manner as described above with respect to FIG. 1. The system 400 further includes a light source 402 and a second EDM tool 404. The voltage source 104 can be configured to establish a potential difference between the workpiece 102 and the second EDM tool 404 such that the second EDM tool 404 performs EDM of the workpiece 102 at a second cut location 406. The light source 402 is configured for flood illumination of the workpiece 102. For example, the light source 402 can illuminate the entirety of at least one side of the workpiece 102. Thus, the light source 402 can illuminate the cut location 120 of the first EDM tool 108 and the cut location 406 of the second EDM tool 404 simultaneously. The system 400 can further include additional light sources 408, 410 that are configured to illuminate different portions of the workpiece 102, thereby facilitating performance of EDM at substantially any location on or in the workpiece 102.

In other embodiments, the illumination system 112 includes the focusing optics 130, which can be configured to focus the light emitted by the light source 128 to a localized region on or within the semiconductor workpiece 102. By way of example, and referring again briefly to FIG. 3, focusing optics (e.g., the focusing optics 130) can be configured to focus the second light 306 to a spot proximal to the cutting location 301 in the semiconductor 302. By focusing light to a spot proximal to a known desired cutting location, the illumination system 112 can concentrate the optical power of the light source 128 to better improve the local conductivity of the workpiece 102 proximal to the cutting location than flood illumination for a same optical power.

Some semiconductors have a low intrinsic conductivity. Therefore, and referring once again to FIG. 1, when the cutting location 120 is far from the electrode 106, the electrical resistance of a conductive path 132 from the cut location 120 to the electrode 106 can be relatively high. This high resistance can degrade the EDM performance of the EDM tool 108 in the workpiece 102. Therefore, in some embodiments, the illumination system 112 can be configured to illuminate the workpiece 102 along the conductive path 132 from the cut location 120 to the electrode 106. For example, the focusing optics 130 can be configured to focus light emitted by the light source 128 (or other light source included in the illumination system 112) along the conductive path 132. Since the conductive path 132 may be disposed within the bulk of the semiconductor workpiece 102, the focusing optics 130 can be configured to focus light emitted by the illumination system 112 to locations within the bulk of the workpiece 102 that are proximal to the conductive path 132. In other embodiments, the illumination system 112 can be configured for flood illumination of the workpiece 102 at a location on a surface of the workpiece 102 that is aligned with the conductive path 132.

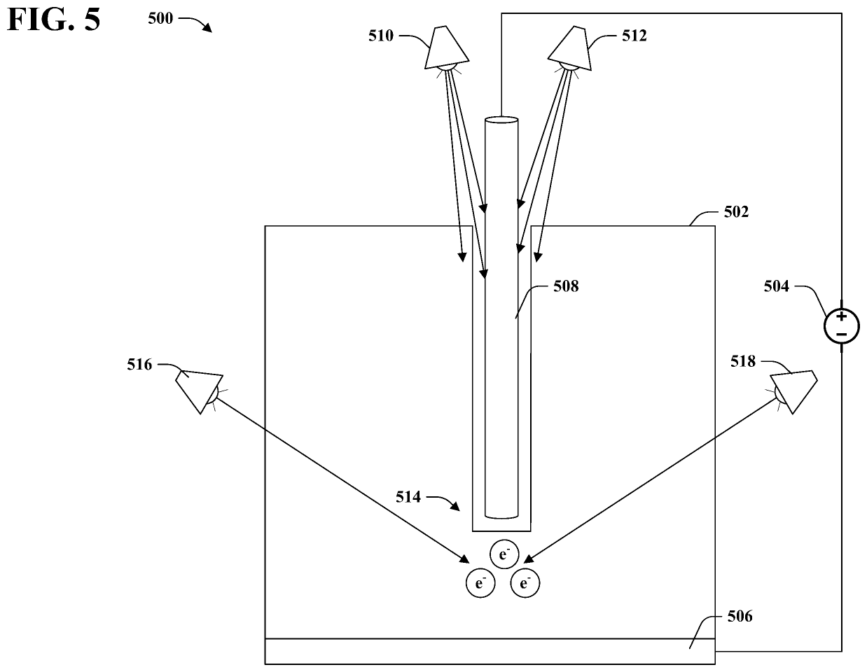

As EDM of the workpiece 102 proceeds, either or both of the conductive path 132 or the cut location 120 of the EDM tool 108 can be disposed at sufficient depth within the semiconductor workpiece 102 that light emitted by the light source 128 that is above the bandgap energy of the semiconductor workpiece 102 is not readily able to stimulate free charge carriers at the cut location 120 or along the conductive path 132. For example, an average penetration depth of the light emitted by the light source 128 can be 5 centimeters or less, whereas the cut location 120 may be disposed ten or more centimeters within the workpiece 102. By way of further example, and referring now to FIG. 5, an exemplary drill or plunge EDM system 500 is shown. The system 500 includes a semiconductor workpiece 502, a voltage source 504, an electrode 506 by way of which the voltage source 504 is electrically connected to the workpiece 502, a plunge EDM tool 508, and two light sources 510, 512. The light sources 510, 512 can be light sources that have photon energies above the bandgap energy of the semiconductor 502. The light sources 510, 512 can readily stimulate free charge carriers in the semiconductor 502, but the light emitted by these sources 510, 512 may be unable to penetrate to the depth of a cut location 514 due to absorption of the light by electrons in the workpiece 502 or obscuring of the cut location 514 by the EDM tool 508 itself.

In various embodiments, the illumination system 112 can be configured to stimulate MPA within the semiconductor workpiece 102. The light source 128 can be configured to emit light that has a photon energy below the bandgap energy of the semiconductor workpiece 102. Photons that have energies below the bandgap energy of the semiconductor workpiece 102 can penetrate deeply into the workpiece 102 without being absorbed by electrons of the workpiece 102 since the single photons do not have sufficient energy to stimulate transition of electrons from the valence band to the conduction band of the semiconductor workpiece 102. The focusing optics 130 are configured to focus the light emitted by the light source 128 to a focal spot within the workpiece 102 and proximal to a cut location at which EDM is desirably performed. At the focal spot, MPA occurs in the bulk of the semiconductor workpiece 102, yielding free charge carriers that increase the conductivity of the semiconductor workpiece 102 proximal to the focal spot. In other words, electrons in the workpiece 102 can transition from the valence band to the conduction band of the semiconductor by absorption of multiple photons that each have energies below the bandgap energy of the semiconductor 102, thereby yielding free charge carriers. Since MPA requires high intensities of light, in embodiments wherein the illumination system 112 is configured to perform MPA, the light source 128 can be or include lasers, such as a femtosecond laser, that are capable of providing pulses with high peak power.

By way of further example, and referring once again to FIG. 5, the system 500 can further include light sources 516 and 518 that are configured to emit light having photon energies below the bandgap energy of the semiconductor workpiece 502. Light emitted by the light sources 516, 518 can penetrate into the semiconductor workpiece 502 to a depth sufficient to create free charge carriers proximal to the cutting location 514.

The EDM control component 126 can control the focusing optics 130 to move the focal spot along a desired machining path as the EDM tool 108 progresses through the workpiece 102. In some embodiments, the EDM control component 126 can control the focusing optics 130 such that the focal spot lies along the conductive path 132 within the semiconductor 102. The illumination system 112 can include multiple light sources configured to stimulate MPA in the semiconductor workpiece 102. Each of the light sources can be configured to illuminate a different focal spot within the semiconductor workpiece 102. Hence, the illumination system 112 can be configured to stimulate free charge carriers in the workpiece 102 by MPA proximal to the cutting location 120 and along the conductive path 132 simultaneously.

It is to be understood that in some embodiments, the illumination system 112 can include light sources of different wavelengths (i.e., different photon energies) or different illumination patterns so that the illumination system 112 can stimulate charge carriers in the semiconductor 102 in different ways. By way of example, and not limitation, the illumination system can include a combination of any or all of light sources configured for flood illumination, light sources configured for localized spot illumination, light sources with photon energies above but close to the bandgap energy of the semiconductor 102, and/or light sources with photon energies below the bandgap energy of the semiconductor 102. In various embodiments, the illumination system 112 can include multiple light sources that emit multiple beams of light that are directed into the workpiece from different directions. The illumination system 112 can be configured such that the multiple beams of light coincide at a location or multiple locations in the workpiece 102 where EDM is desirably performed.

The EDM system 100 can be configured to perform EDM of the workpiece 102 at various temperatures. In some exemplary embodiments, the EDM system 100 performs EDM of the workpiece 102 (e.g., the illumination system 112 illuminates the workpiece 102 and the voltage source 104 applies a voltage between the electrode 106 and the EDM tool 108) when the workpiece 102 and the dielectric fluid 118 are at temperatures less than 100° C. In further embodiments, the EDM system 100 performs EDM of the workpiece 102 at less than or equal to 30° C. In still further embodiments, the EDM system 100 performs EDM of the workpiece 102 at less than or equal to 20° C.

While various aspects have been described herein with reference to the exemplary wire-EDM system 100 and the exemplary plunge EDM system 500, it is to be understood that technologies described herein are similarly applicable to wire EDM, drill/plunge EDM, or die EDM applications. In die EDM, the EDM tool is a conductive element that can have a shape that has a flat surface or a non-flat surface, wherein an inverse of the surface profile of the EDM tool is machined into a surface of the workpiece at a cutting location of the EDM tool. Various aspects described with respect to the systems 100, 500 are to be understood to be generally applicable to EDM systems of various configurations.

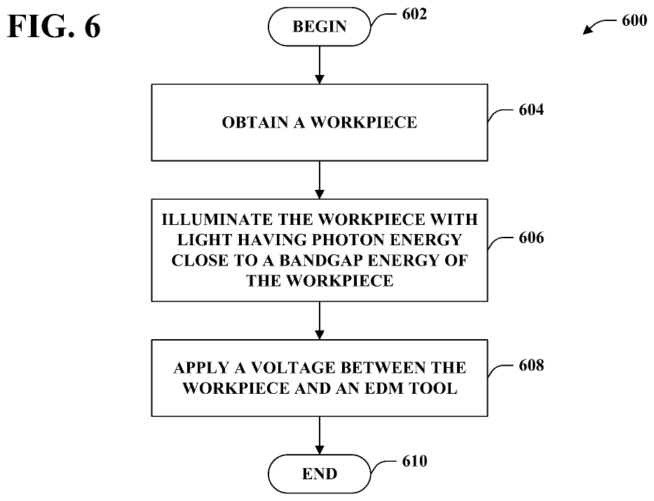

FIG. 6 illustrates an exemplary methodology relating to EDM of semiconductors. While the methodology is shown and described as being a series of acts that are performed in a sequence, it is to be understood and appreciated that the methodology is not limited by the order of the sequence. For example, some acts can occur in a different order than what is described herein. In addition, an act can occur concurrently with another act. Further, in some instances, not all acts may be required to implement a methodology described herein.

Moreover, the acts described herein may be computer-executable instructions that can be implemented by one or more processors and/or stored on a computer-readable medium or media. The computer-executable instructions can include a routine, a sub-routine, programs, a thread of execution, and/or the like. Still further, results of acts of the methodologies can be stored in a computer-readable medium, displayed on a display device, and/or the like.

Referring now to FIG. 6, a methodology 600 that facilitates EDM of semiconductors is illustrated. The methodology 600 begins at 602, and at 604 a workpiece is obtained. The workpiece can be any of various semiconductors, such as silicon carbide, gallium nitride, germanium, gallium arsenide, or the like. At 606, the workpiece is illuminated with light that has a photon energy close to a bandgap energy of the workpiece. In an exemplary embodiment, the light can have a photon energy that is less than or equal to 110% of the bandgap energy of the workpiece, less than or equal to 105% of the bandgap energy of the workpiece, less than 102% of the bandgap energy of the workpiece, or less than 100.5% of the bandgap energy of the workpiece. The illumination of the workpiece causes an electrical conductivity of the workpiece to increase. At 608, a voltage is applied between the workpiece and an EDM tool. The EDM tool can be a conductive element such as a wire or a surface that may be flat or non-flat. The voltage applied between the workpiece and the EDM tool is sufficiently great to cause an electrical discharge between the workpiece and the EDM tool, thereby removing material from the workpiece. The methodology 600 ends at 610.

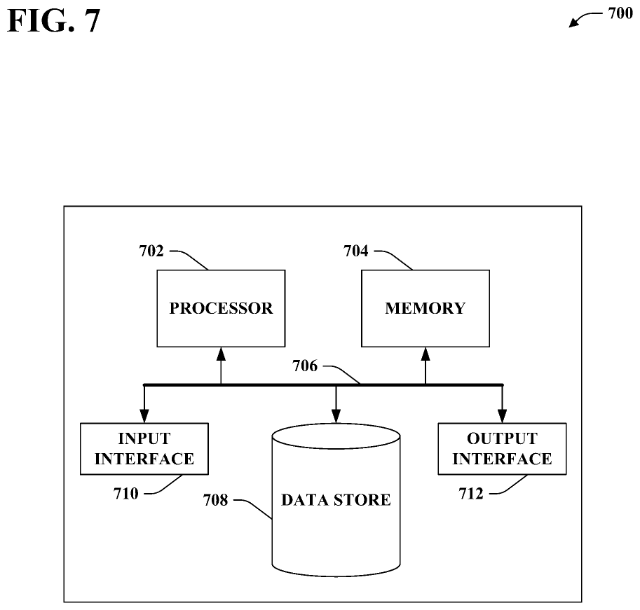

Referring now to FIG. 7, a high-level illustration of an exemplary computing device 700 that can be used in accordance with the systems and methodologies disclosed herein is illustrated. For instance, the computing device 700 may be used as a control device in a system for EDM (e.g., as the controller 110 in the systems 100, 400). The computing device 700 includes at least one processor 702 that executes instructions that are stored in a memory 704. The instructions may be, for instance, instructions for implementing functionality described as being carried out by one or more components discussed above or instructions for implementing one or more of the methods described above. The processor 702 may access the memory 704 by way of a system bus 706. In addition to storing executable instructions, the memory 704 may also store EDM control parameters such as operating voltage, machining instructions indicative of locations within a workpiece that are desirably machined by EDM, or the like.

The computing device 700 additionally includes a data store 708 that is accessible by the processor 702 by way of the system bus 706. The data store 708 may include executable instructions, EDM control parameters, machining instructions, etc. The computing device 700 also includes an input interface 710 that allows external devices to communicate with the computing device 700. For instance, the input interface 710 may be used to receive instructions from an external computer device, from a user, etc. The computing device 700 also includes an output interface 712 that interfaces the computing device 700 with one or more external devices. For example, the computing device 700 may display text, images, etc. by way of the output interface 712.

It is contemplated that the external devices that communicate with the computing device 700 via the input interface 710 and the output interface 712 can be included in an environment that provides substantially any type of user interface with which a user can interact. Examples of user interface types include graphical user interfaces, natural user interfaces, and so forth. For instance, a graphical user interface may accept input from a user employing input device(s) such as a keyboard, mouse, remote control, or the like and provide output on an output device such as a display. Further, a natural user interface may enable a user to interact with the computing device 700 in a manner free from constraints imposed by input device such as keyboards, mice, remote controls, and the like. Rather, a natural user interface can rely on speech recognition, touch and stylus recognition, gesture recognition both on screen and adjacent to the screen, air gestures, head and eye tracking, voice and speech, vision, touch, gestures, machine intelligence, and so forth.

Additionally, while illustrated as a single system, it is to be understood that the computing device 700 may be a distributed system. Thus, for instance, several devices may be in communication by way of a network connection and may collectively perform tasks described as being performed by the computing device 700.

Various functions described herein can be implemented in hardware, software, or any combination thereof. If implemented in software, the functions can be stored on or transmitted over as one or more instructions or code on a computer-readable medium. Computer-readable media includes computer-readable storage media. A computer-readable storage media can be any available storage media that can be accessed by a computer. By way of example, and not limitation, such computer-readable storage media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, include compact disc (CD), laser disc, optical disc, digital versatile disc (DVD), floppy disk, and blu-ray disc (BD), where disks usually reproduce data magnetically and discs usually reproduce data optically with lasers. Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio and microwave are included in the definition of communication medium. Combinations of the above should also be included within the scope of computer-readable media.

Alternatively, or in addition, the functionality described herein can be performed, at least in part, by one or more hardware logic components. For example, and without limitation, illustrative types of hardware logic components that can be used include Field-programmable Gate Arrays FPGAs, ASICs, Application-specific Standard Products (ASSPs), System-on-a-chip systems (SOCs), Complex Programmable Logic Devices (CPLDs), etc.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electrical discharge machining (EDM) system, comprising:
a workpiece, the workpiece comprising a semiconductor material;
an EDM tool;
a voltage source that is electrically connected to the EDM tool and the workpiece;
an illumination system that is configured to illuminate the workpiece with light having a photon energy that is less than or equal to 110% of a bandgap energy of the semiconductor material; and
a controller that is configured to control the voltage source to establish an electric potential difference between the workpiece and the EDM tool such that an electrical discharge occurs between the workpiece and the EDM tool, wherein the electrical discharge causes material to be removed from the workpiece.

2. The EDM system of claim 1, wherein the illumination system is configured to illuminate the workpiece such that multi-photon-absorption (MPA) occurs at a focal spot within the workpiece.

3. The EDM system of claim 1, wherein the illumination system is configured to illuminate the workpiece at a location at which the electrical discharge causes the material to be removed from the workpiece.

4. The EDM system of claim 1, further comprising an electrode that is connected to the workpiece, wherein the voltage source is electrically connected to the workpiece by way of the electrode, and wherein the illumination system is configured to illuminate the workpiece along a path extending between the electrode and a location at which the electrical discharge causes material to be removed from the workpiece.

5. The EDM system of claim 1, further comprising:
a dielectric liquid; and
a container, the dielectric liquid and the workpiece positioned inside the container such that the workpiece is at least partially immersed in the dielectric liquid.

6. The EDM system of claim 5, wherein the dielectric liquid is one of:
water; or
a dielectric oil.

7. The EDM system of claim 1, wherein the electric potential difference is less than or equal to 400V.

8. The EDM system of claim 1, wherein the EDM tool is a conductive wire.

9. The EDM system of claim 1, wherein the EDM tool comprises a conductive surface.

10. The EDM system of claim 9, wherein the conductive surface is a non-flat surface.

11. A method for performing electrical discharge machining (EDM), comprising:
obtaining a workpiece, the workpiece comprising a semiconductor material;
illuminating the workpiece with light having a photon energy that is less than or equal to 110% of a bandgap energy of the semiconductor material; and
applying a voltage between the workpiece and an EDM tool such that an electrical discharge occurs between the workpiece and the EDM tool, wherein the electrical discharge causes material to be removed from the workpiece.

12. The method of claim 11, wherein the photon energy is less than the bandgap energy of the semiconductor material, the illuminating of the workpiece is configured to cause multi-photon absorption in the workpiece.

13. The method of claim 11, wherein the semiconductor material is silicon carbide, wherein the light has a photon energy between 3.26 electron volts and 3.423 electron volts.

14. The method of claim 11, wherein the workpiece comprises silicon, wherein the photon energy is between 1.12 electron volts and 1.176 electron volts.

15. The method of claim 11, wherein the semiconductor material is germanium, wherein the photon energy is between 0.67 electron volts and 0.70 electron volts.

16. The method of claim 11, wherein the semiconductor material is gallium arsenide, wherein the photon energy is between 1.43 electron volts and 1.50 electron volts.

17. The method of claim 11, wherein the semiconductor material is gallium nitride, wherein the photon energy is between 3.4 electron volts and 3.57 electron volts.

18. The method of claim 11, wherein the voltage is applied when the workpiece is at a temperature of less than 100° C.

19. A system for electrical discharge machining (EDM), comprising:
a workpiece, the workpiece comprising a semiconductor material;
an EDM tool;
a voltage source that is electrically connected to the EDM tool and the workpiece;
an illumination system that is configured to illuminate the workpiece with light; and
a controller that is configured to control the voltage source to establish an electric potential difference of less than or equal to 400V between the workpiece and the EDM tool, wherein responsive to the electric potential difference being established an electrical discharge occurs between the workpiece and the EDM tool, wherein the electrical discharge causes material to be removed from the workpiece.

20. The system of claim 19, wherein the illumination system is configured such that the light has a photon energy of less than or equal to 110% of a bandgap energy of the semiconductor material.
